(19) United States
(12) Patent Application Publication
(10) Pub. No.: US 2011/0177327 A1
(43) Pub. Date: Jul. 21, 2011

(54) BARRIER LAYERS, ITS USES AND A PROCESS FOR PREPARATION THEREOF

(76) Inventors: Shahab Jahromi, Maastricht (NL); Constantinus Simon Maria Liebregts, Helmond (NL)

(21) Appl. No.: 13/003,376

(22) PCT Filed: Jul. 7, 2009
(86) PCT No.: PCT/EP09/58634

§ 371 Date: Apr. 11, 2011

(30) Foreign Application Priority Data
Jul. 10, 2008 (EP) 08160126.2

(51) Int. Cl. B32B 3/00; C23C 14/12; B32B 15/08; B32B 27/34; C08K 5/3492

(52) U.S. Cl. 428/336; 118/725; 427/255.6; 428/458; 428/474.4; 428/477.7; 524/100

(57) ABSTRACT

The invention relates to the use of melam deposited on a substrate, in applications requiring high humidity resistance, such as further processing comprising retort or metal deposition, or applications such as solar or display. Melam to melamine ratio (w/w) in the barrier layer is in the range from 3:1 to 50:1. The retortable laminate comprises two plastic films and in between a crystalline melam layer, the laminate having a lamination strength of about 2 N/inch or more as measured in a 90 degree tensile testing at 30 mm/min

The invention relates to uses of layers with barrier properties. The invention further relates to a process and apparatus for the preparation thereof and articles with such layer with barrier properties.

Laminates are used in the packaging, electronic and other industries. Often, the laminates need good barrier properties like low oxygen or water vapour transmission rates. Plastic or paper films need to be coated with one or more layers improving the barrier properties. Yet, the adhesion between the films needs to be sufficiently high. Substrates, for example polyolefin or polyester films coated with a metal or metal oxide, like e.g. aluminum, aluminum oxide, magnesium oxide, silicium oxide optionally with melamine, or melamine as such are known. The film with barrier properties is generally further laminated with e.g. a further polyolefin film while using an adhesive, or with extrusion lamination. These laminates are for example used in the packaging or electronic industry. Such laminates can have good barrier properties. However the metal layers that are used to enhance the barrier properties are non-transparent, cause environmental concern as they cause difficulties in recycling, and its contents is not micro-waveable. Metal oxide layers that are used to enhance barrier properties are easily damaged, expensive and require high level operators to reliably produce laminates. PVDC type of barrier films cause environmental concerns because of its chlorine content. EVOH type of barrier films are highly moisture sensitive.

Melamine is a triazine, and is used as oxygen barrier layer. U.S. Pat. No. 6,632,519, DE 19917076 and WO 2004/101662 describe the use of melamine as barrier layer. Jahromi in Macromolecules ACS 1 Oct. 2000, pp7582-7587 furthermore shows a grain crystalline melamine structure, deposited on PET or OPP substrates. Layers from melamine are moisture sensitive; the oxygen barrier properties diminish at >60%RH, and melamine does not show water barrier properties. In WO 2008/083934, published after the priority date of the present patent application, it is suggested to apply a protective coating to melamine. Although this gives a certain improvement of the barrier properties with respect to water sensitivity, the water sensitivity still is substantial.

One specific example of the use of certain laminates in packages is a so-called retortable packaging. This package is—with its final content—subjected to sterilizing conditions (for example slightly above 121° C. for 30 min up to for example 3 hr at 130° C. in a steam atmosphere, generally at pressures above 10 bar). Such laminates require specific plastic films (as for example PE is not able to withstand these temperatures) and specific adhesives. Further, these packages often need to be transparent, precluding the use of alumina. Other examples of the use for these laminates include hot filling applications and applications where the packaged food is boiled at ambient pressure.

### OBJECTS

It is an object of the invention to provide a material for vapour deposition of coatings that are able to withstand high humidity and optionally high temperature.

It is a further object of the invention to provide a laminate having good barrier properties and a good lamination strength, which is microwaveable and retortable, i.e. preserve barrier properties after retort process.

It is a further object of the invention to provide a laminate having good barrier properties and a good lamination strength, which is suitable for hot filling and/or boiling, i.e. preserve barrier properties after such processes.

It is yet another object of the invention to provide a metal coated paper or carton based package with good barrier properties with in-line coating layers.

It is yet another object of the invention to provide a metal oxide coated plastic film with improved barrier properties

It is another object of the invention to provide a laminate for electronic applications.

It is another object of the invention to produce rigid or flexible electronic devices such as displays and solar cells with sufficient protection against external environment like moisture.

It is another object of the invention, to provide suitable dielectric layers.

### SUMMARY

One or more of the above objects are achieved with the current invention, providing for the use of vapour deposited melam in applications requiring barrier properties resistant to high humidity.

The invention furthermore provides a substrate and a thin layer of a crystalline melam compound, in an article which is subjected to environmental stress which deteriorates melamine.

This invention relates to the use of melam in thin layer vapour deposition, as it appeared that the crystalline melam layer is a continuous crystalline layer. In contrast, melamine or melem crystallize in a grain structure. It was unexpected that melam crystallizes differently than melamine or melem.

Unexpectedly, the substrate with a crystalline melam layer can be used to make laminates of the present invention, which can be used in packaging for microwaveable food applications, and can be easily recycled.

It was furthermore unexpected that melam could improve oxygen and vapour barrier properties of metal oxide coatings like AlOx and SiOx, also after hot fill or retort of packagings.

It was furthermore unexpected that melam adheres much better than melamine on metallised coatings such as aluminium and metal oxide coatings like AlOx and SiOx.

The good adhesion of melam to metal layers makes a thin layer of melam a very suitable insulating layer between two metal deposited layers.

U.S. Pat. No. 6,632,519, DE 19917076 and WO 2004/101662 describe the use of triazines, and specifically of melamine as barrier layer. Even though melam is mentioned as possible triazine, no specific teaching with respect to the use, the process, the apparatus or to the advantages of melam is apparent. The same is true for WO 2008/083934, published after the priority date of the present patent application.

It appeared that when applying melam in a way described for melamine, and adjusting the temperature of the evaporator to the higher sublimation point of melam, layers were obtained with little melam.

It is another object of the present invention to provide a process and apparatus to achieve a triazine layer comprising more than about 70 wt % of melam.

The invention furthermore relates to equipment and a process for the application of melam, the equipment comprising a vacuum chamber, an evaporator with an oven comprising heating element and a shutter over the length of the to be coated substrate, the heating element being able to heat the content of the oven up to 310-390° C. and comprising means to preclude decomposition of the melam by long exposure to high temperatures.

In a preferred embodiment of the present invention, the layer of melam on a substrate comprises melam and melamine in a ratio (w/w) of 3:1 to 50:1

### DETAILED DESCRIPTION

The melam layer consists in general of about 40% or more of melam, preferably, about 50% or more of melam, more preferably of about 70% or more, and even more preferably of about 90% or more by weight, of melam. Other compounds that could be present in lower amounts are melamine, alumina and additives originating from the substrate. The amount of melam is about 98% or lower and 2% or more melamine, and preferably about 95% or lower and 5% or more melamine.

Generally, it appeared to be very difficult to have a continuous deposition of a high percentage of melam in a roll-to-roll or other (semi-continuous) system that coats for more than 15 or 20 min. Either the temperature needs to be relatively low, or the period that the melam is heated needs to be relatively short. Hence, in the present invention, generally, the coating contains an amount of about 5 wt % melamine or more, and often about 10 wt % melamine or more. It appeared that low water vapour transmission and oxygen transmission values under high humidity could be achieved with melam/melamine ratios (w/w) of about 3:1 or higher, such as about 5:1.

It has appeared to the inventors, that when applying melam, after a relatively short period of time at high temperatures, the melam starts to decompose in the evaporator, leading to the formation of melamine. The melamine also evaporates (even preferentially, as it has a lower vapour pressure), and forms as well a deposed layer on the surface of the plastic film. Melamine strongly deteriorates the properties of the melam layer.

Thus, the present invention furthermore provides for a process of making a melam coated film, wherein a roll of plastic is subjected to a roll-to-roll coating process in a vacuum chamber taking more than 20 min, the process comprising means to preclude decomposition of the melam, such that a layer of melam is obtained on the film which has a ratio (w/w) of melam to melamine of higher than 3:1, and lower than 50:1, preferably higher than 4:1 and lower than 20:1.

Furthermore, the present invention provides for a process of making a melam coated substrate, wherein discrete substrates are consecutively subjected to a coating process in a vacuum chamber taking more than 20 min, the process comprising means to preclude decomposition of the melam, such that a layer of melam is obtained on the substrate which has a ratio (w/w) of melam to melamine of higher than 3:1, and lower than 50:1, preferably higher than 4:1 and lower than 20:1

In practice it is important to be able to coat long rolls (>10,000 meters) at high speeds (>5 m/s). The rolls should be coated with thickness between 100-400 nm. The coating conditions in terms of temperature, crystalline type, and evaporator design should be chosen in such a way to allow production of melam coated rolls with above characteristics.

Several measures are available to prevent decomposition of melam into melamine. Firstly, it is possible to keep a relatively low temperature in the evaporator; this will cause a relatively low evaporation rate. This can be acceptable if a thin layer of melam is sufficient. In other cases it can be preferred to use of a number of evaporators in series. Secondly, it is possible to regularly remove decomposed material. Thirdly, it is possible to have an oven at higher temperature, and regularly add some melam to the oven. Such oven can in that case be relatively small in cross-section and can have a high heating surface per amount of melam powder.

The composition of the layer of deposited triazine materials can be measured with HPLC.

The thickness of the crystalline melam layer as formed on the substrate in the vapour-depositing step depends on its intended purpose, and can thus vary within wide limits. Preferably, the thickness of the layer is about 2 μm or less, more preferably about 0.5 μm or less, and even more preferably about 0.2 μm or less as with such lower thickness the transparency is improved. The thickness may be for example about 200 nm or less, or 100 nm or less for cost reasons. The minimum thickness is preferably about 2 nm or more, more preferably about 10 nm or more, and even more preferred about 15 nm or more as such thickness improves the protective properties. For example, the thickness can be about 20 or 30 nm or more.

The crystalline melam layer may be a single layer, it is however also possible that on the crystalline layer further layers are present, for example further layer of triazine, a printing, a further polymer layer and/or a cured resin layer.

A further embodiment of the invention relates to a laminate comprising a layer of crystalline melam further comprising a cured resin layer, which resin before cure comprised an azine-formaldehyde or phenol-formaldehyde resin.

In an alternative embodiment of the invention the laminate comprising a layer of crystalline melam does not comprise a cured resin layer, which resin before cure comprised an azine-formaldehyde or phenol-formaldehyde resin. It appeared that in contrast to melamine, such further coating does not improve properties substantially. Thus, it is preferred not to apply such an additional layer as to lower costs.

The melam layer can be applied directly on a substrate, like a plastic film as a sole barrier layer, but can as well be used as layer on other barrier layers such as metal or metal oxide layers. Furthermore, —when used on a metal layer, melam has good adhesion and insulating properties, allowing a further metal layer to be applied.

In case ultra high barrier properties are required, it may be advantageous to apply a number of melam layers, which can be separated by leveling layers. Suitable leveling layers generally are fluid curable coatings. Preferably, the coatings are radiation curable such as UV- and EB curable coatings. Suitable leveling layers are for example cured acrylate coatings, epoxide coatings, vinyl ethers and the like.

The melam layer can be applied directly on a substrate, but the substrate can be pretreated with a coating, such as for example a coating with a high modulus and/or low expansion when comparing zero and high humidity (like 0 and 100% RH or dry and immersed in water). Suitable coatings are nano-silica based cross linked coatings, highly cross-linked acrylate coatings and the like. Such coatings are in particular advantageous in case the substrate has a high expansion under wet conditions. The loading of the nano-particles is preferably above 10 volume % and more preferably above 15 volume %.

It is preferred to use melam in retortable laminates; it was unexpected that the crystalline melam layer in the laminate is (even without a protective coating) able to withstand retort conditions.

In another embodiment, it is preferred to use the laminate for packaging that needs barrier properties at high humidity (>80% RH).

In a further embodiment of the present invention, the product is a laminate comprising an adhesive layer between the melam layer and a plastic film.

In a further embodiment, the laminate comprises a pattern or figure on the melam layer.

In a further embodiment, a film is directly extruded on the melam layer, which may be printed.

In a further embodiment, the packaging comprises a PET substrate, melam layer, poly-olefin layer, paper or cardboard layer and a further polyolefin layer.

In a further embodiment, the laminate is a retortable laminate, wherein the substrate comprises one or more plastic layers independently chosen from PP, PET and Polyamide.

In another embodiment, the substrate is a plastic substrate, coated with a metal oxide like AlOx or SiOx. Such substrate allows the combined barrier properties of a metal oxide and melam in a transparent high barrier film with excellent oxygen and water vapour barrier.

In another embodiment, the substrate is a plastic substrate, coated with a metal layer such as for example alumina. As described in WO2009/012878, the adhesion between a deposited metal or metal oxide layer and melamine layer is not acceptable. It appears—unexpectedly—that the adhesion between metal or metal oxide layers and melam is good, thereby obviating the need of adhesion promoters, and allowing better combined barrier properties.

In yet another embodiment, crystalline melam layers are unexpectedly well suitable for use in very high (or even ultra-high) barrier layers for flexible packaging: Similar to application in paper; plastic film/melam/oxides (AlOx, SiOx, AlOx—SiOx)/melam, or alternatively, plastic film/oxides/melam build-up can give very good barrier flexible packaging that can withstand retort. Again all layers are applied in-line. The extremely good high temperature resistance properties of melam allow the application of AlOx and/or SiOx layers on such melam layer.

In a further embodiment, a film is directly extruded on the crystalline melam layer, which may be printed. The use of melam has the advantage, that the temperatures which are regularly applied (up to 400° C.) can be used as such. In contrast, it is necessary to lower the temperature of the lamination if melamine is used as triazine.

In a further embodiment, a metal or metal oxide layer is directly deposited on a melam layer. The combined structure has improved oxygen and water barrier properties. In case of melamine, it is not possible to deposit a pristine layer of metal or metal oxide on top of melamine, because, due to thermal heating of the metal or metal oxide layer, melamine tends to sublime upon deposition of metal or metal oxide layer. Melam, due to its lower vapour pressure and higher sublimation temperature, does not sublime upon vapour deposition of metal or metal oxide layer resulting in formation of a pristine layer on top of melam.

In a further embodiment, the melam layer is applied in a sandwich between two layers of deposited metal, generally on a plastic film or a rigid substrate. In the resulting laminate melam acts as a dielectric insulating layer

In a further embodiment, the invention relates to a laminate being a retortable laminate, comprising plastic layers independently chosen from PP, PET and Polyamide, and a crystalline melam layer. Preferably, the melam layer is without a protective coating that has reacted with the melam. The laminate further will comprise an adhesive which is suitable to withstand retorting conditions. A typical laminate structure for retort applications consist of PET/Melam/print layer/adhesive/OPA (oriented polyamide)/CPP(cast polypropylene)

In a preferred embodiment of the invention, the laminate with retortable properties is sealable.

Preferably the composite layer, when laminated at the side of the crystalline melam layer with an adhesive and a plastic film is able to exhibit a lamination strength of about 2.5 N/inch or more, more preferably of about 3 N/inch or more, even more preferably of about 3.5 N/inch or more as measured with a tensile testing apparatus at 30 mm/min and at 90 degree. Generally, the upper limit of the lamination strength is not critical, but generally, this will be about 20 N/inch or less. The lamination of the composite layer for testing preferably is done with an appropriate urethane adhesive and laminated with a 10 μm thin polyethylene film. Thereafter, the lamination strength of the two films can be measured, and the failure mode can be observed. An appropriate adhesive is an adhesive that has such adhesion strength that the failure mode is not observed on the adhesion layer. The adhesion may be so high that the plastic film breaks. The value of the force necessary to break a film can in that case be taken as value for adhesion.

The substrate comprises a material that serves as carrier, and this generally will be a plastic or paper in the form of a film or web.

Flexible packaging materials generally are based on film or sheet like materials, hereinafter named film.

The composite layer according the invention, in particular the ones with a film as substrate may be used as such, but can also be applied on plastic, paper, cardboard, steel and the like.

In one embodiment of the invention, the layer is part of a packing for food and beverage products. Suitable food and beverage products include, but are not limited to coffee beans or milled coffee beans, beer, fruit juice, tomato ketchup, milk, cheese, prepared food and the like. The packaging can also be used for other products, such as for personal care and pharmaceutical products.

In another embodiment of the present invention, the substrate is a plastic container made from thermoplastic polymer. Suitable thermoplastic polymers include polyesters, polyolefins and polyvinylchloride.

Plastic containers can be bottles, casks, kegs, bag-in box and other forms that can held liquid. Part of the content may be solid, like olives, cheese, onions, pickles, spices and citrus or other fruit. In a preferred embodiment of the present invention, the container is a bottle. In another embodiment of the invention, the container is a cask.

In one embodiment of the invention, the polymer is a thermoplastic polyester and optionally other polymers, wherein the polyester is present in at least 80 weight % of the thermoplastic material. The polyester preferably contains at least 80% polyethylene terephthalate; other polymers that may be blended with PET are polyethylene naphthalene, polyamide, polybutylene-terephthalate and the like. Preferably, the PET container consists of about 90% or more of PET. The PET container may be a monolayer bottle or a multilayer container. Multilayers preferably are used with recycled PET as an outer layer, and virgin PET as an inner layer.

In another embodiment of the present invention, the container is made from polymers based on naturally occurring material such as poly-lactic-acid polyester.

For example PET bottles can be prepared by injection moulding of pre-forms, and subsequent blow-forming the preform into an actual bottle-shape.

Containers from polyolefins include bottles, casks and other forms from preferably polyethylene or polypropylene. Such containers are generally made through blow moulding.

The containers as described above are holding the liquid. In one embodiment of the invention, the container is held—optionally in part—in a strengthening member. Suitable strengthening members include but are not limited to a box of carton or wood or on an additional bottom.

The containers with barrier properties can be used for food and beverages, personal care, pharmaceutical and other applications where such packaging can be used. The contents generally will be of fluid nature like beer, juice, oil or unguent. However, solid content like pharmaceuticals may need an oxygen barrier as well.

Containers may have a useful content of 0.05, or higher, such as 0.2 litre (L) or higher. Suitable examples of sizes include 0.05 L, 0.1 L, 0.2 L, 0.25 L, 0.33 L, 0.5 L. one pint, 1 L, 1.5 L, 2 L, 2.5 L, 3 L, one gallon, 5 L, 10 L and the like. Larger volumes may be suitable as well, and the upper limit is not critical. One could imagine casks, kegs or bag-in-box preferably for food service and industrial applications with sizes of 50L, to 100 L up to 2000, 5000, 10,000 or 50,000 litre suitable to be used with beer, wine or liquid food ingredients.

Preferably, the melam is deposited on the surface of the container, which can be the inside, the outside or both. In a further preferred embodiment, the deposited layer is physically protected by a protective layer, which can be a thermoplastic shrinkable film, a thermosetting resin (like a coating) or the like.

In another embodiment, crystalline melam layers are unexpectedly well suitable for use in pre-coated and top coated metallized paper for packaging. Current papers for metallization are special types of paper with the structure: Paper/clay coating/precoating/Alumina/topcoating. The paper is usually calendared to smooth the surface. Then a clay coating is applied by the paper manufacturer to smoothen the surface even more. This paper is then used for metallization. First, a pre-coat is applied to enhance adhesion of Al-layer, then an alumina layer is applied, and thereafter, a topcoat to induce printability. Both pre- and topcoat are applied off-line and very expensive. It appeared possible to apply special triazine coatings like melam, in-line both as pre-coat and topcoat. For this, a webcoater with three evaporation sources can be used. First, from a triazine evaporator (pre-coat), a melam coating is applied, then Aluminum source, and then again a triazine evaporator as topcoat. Melam is an ideal material because of its high vapor pressure, i.e. upon deposition of Al, they do not sublime resulting in mixing of Al with triazine vapour. When melamine would be used, the triazine layer would evaporate. In this way a pristine layer of Al can be applied on an in-line precoat. The advantages are better barrier of Al and elimination of very tedious and expensive offline pre- and topcoat. Melamine could be used as top-coat, because that coating is not so much put under high temperature stress.

In another embodiment, crystalline melam layers are unexpectedly suitable for use in solar systems, as either inorganic (crystalline and amorphous) or organic materials (dye-sensitized) must be protected against oxygen and water. Melam is an ideal barrier and encapsulation material for rigid and flexible thin-film photovoltaics with glass, plastic or metal as substrates depending on application. In particular crystalline melam is suitable in the manufacturing of solar cells based on various thin film technologies, including but not limited to using the following materials as photovoltaic compounds: Cadmium Tellluride, Copper-Indium Selenide (CIS), Copper Indium Gallium Diselenide (CIGS), Gallium arsenide (GaAs) multijunction, hybrid cells, Light-absorbing dyes (DSSC), Organic/polymer solar cells, Silicon Thin Films (amorphous silicon, protocrystalline silicon and nanocrystalline silicon), and Nanocrystalline solar cells Currently, often silicium or alumina oxides are used as barrier layers. However, these are too expensive because of the complex technology and high to ultra high vacuum. Furthermore, the layers are brittle.

It appeared that a combination of one or more melam layers as a under- and/or toplayer and one or more metal oxide layers does provide a better solution.

In another embodiment of the invention, stacks of melam layers can effectively protect sensitive devices. Preferably, the melam layers are stacked with intermediate leveling layers, like for example acrylate based coatings. Similarly, melam coatings are very suitable for flexible solar applications.

For example a Dye Solar Cell comprises a layer of nano-particulate titania (Titanium Dioxide) formed on a transparent electrically conducting substrate and photosensitized by a monolayer of dye. An electrolyte, based on an iodide—Tri-iodide redox system, is placed between the layer of photosensitized titania and a second electrically conducting catalytic substrate. This method can be used to produce flexible solar using flexible steel as the substrates. The laminate with active solar components (photovoltaic) can be laminated onto flexible steel. Alternatively the photovoltaic components can be directly printed on top of the steel substrates with the melam as barrier layer perhaps in combination with other transparent barrier layers such as those based on metal oxides. As the last layer the steel substrate may be coated with a layer coating as the protective top layer.

In one embodiment, melam is used as barrier layer in flexible solar applications, preferably as stacks with intermediate leveling layers.

In another embodiment, melam is used as barrier layer in rigid solar applications, preferably as stacks with intermediate leveling layers.

In another embodiment, crystalline melam layers are unexpectedly well suitable for use in an application as barrier coatings with desirable optical characteristics, i.e. this triazine compounds does not absorb in long wavelengths (>500 nm). This is an advantage over inorganic transparent barrier materials. Potential applications are in electronic devices.

In yet another embodiment, crystalline melam layers are unexpectedly well suited for use as stacked barrier layers, optionally in combination with layers to decouple the melam layers like acrylates, for the encapsulation of flexible displays like liquid crystalline displays (LCD), or organic light emitting diode displays (OLEDs), or polymer light emitting displays (PLED), or electrophoretic displays, or electroluminescense displays (EL), or phosphorescent displays. In those flexible displays where semiconductor circuitry, albeit inorganic or organic semiconductor devices, is embedded, for example to drive the individual display elements (pixels or sub-pixels), such melam barrier layers in combination with decoupling layers can also be used to encapsulate these semiconductor devices. In the case of flexible displays, the flexible substrates, such as but not limited to PET, PEN or PES, can be repeatedly coated with a layer of melam and a decoupling layer, such as but not limited to, organic polymers, inorganic polymers, organometallic polymers, hybrid inorganic/organic polymer systems, and silicates. The sensitive display or optionally semiconductor device will be further applied adjacent to the melam barrier stack. For encapsulation of the optional semiconductor device another melam barrier stack is applied on top of the semiconductor device, on top of which the display device is applied. Another flexible substrate with a melam barrier stack is attached on top of the display device for encapsulation. In case a second flexible substrate to encapsulate the display device can be omitted like with OLED, PLED, EL or phosphorescent displays, the melam barrier stack can be applied directly in-line (in vacuum) on top of the sensitive display device to protect against moisture and oxygen.

In another embodiment where an OLED or PLED display is built upon a single rigid glass substrate without a glass or metal encapsulation, one or more melam layers in combination with one or more said decoupling layers can be directly coated in-line (in vacuum) on top of other OLED display stack as encapsulation. Additional layers, for example to provide a further improved water barrier, based on fluor compounds can also be coated in-line. Additional layers can be coated off-line to provide better protection.

In yet another embodiment, crystalline melam layers are unexpectedly well suitable for use as barrier layer, optionally in combination with other layers based on metal oxides, for production of (flexible) displays based on liquid crystalline compounds or organic light emitting diodes (OLEDs). In the case of flexible displays, the flexible substrates, such as PET, can be repeatedly coated with a layer of melam and a layer of metal oxides, such as silicium oxide or aluminum oxide or a combination thereof. In the case of rigid OLED displays, the melam layer can be directly coated in-line (in vacuum) on top of other OLED molecules as the protective layer. Additional layers, for example to provide a further improved water barrier, based on fluor compounds can also be coated in-line. Additional layers can be coated off-line to provide better protection. It furthermore appeared that stacks of melam layers can effectively protect sensitive devices. Preferably, the melam layers are stacked with intermediate leveling layers, like for example acrylate based coatings.

Similarly, melam coatings are very suitable for flexible electronics.

In another embodiment of the invention, the laminate or composite layer is used in or on displays or other electronic products, preferably flexible electronics products. One example of an electronic flexible product is a flexible display.

In another embodiment melam is applied as a barrier layer in displays (both flexible and rigid) based organic light emitting diode (OLEDs) and liquid crystalline displays. OLEDs compounds are particularly sensitive to the action of moisture and oxygen. In the current method of production of rigid displays. The OLED molecules are vapour deposited under vacuum. The final rigid display is sealed under vacuum to prevent the diffusion of oxygen and moisture into display unit. This method is quite expensive and time consuming. Surprisingly we have found that application of melam, directly on top of the OLED molecules as the top layer, significantly increases the life time of such displays without the need to apply various types of sealing systems. It is also possible to coat the melam layer with various types of vapour depositable compounds such as fluorine based compounds, to increase the moisture barrier. A protective top coat can be applied off-line using various wet methods on top of the final stack of vapour depositable compounds (OLED/triazine/fluorine compounds).

In another embodiment, the melam layer is used as dielectric coating between two metal layers, such as for example vapour deposited chromium, copper, silver, aluminium or gold layers.

The barrier properties and/or the adhesion of the melam layer can improve if the substrate is treated first with a primer layer. As the primer various types of compounds can be used. Examples include UV curable monomers such as acrylates and epoxies and various types of thermoset resins such as epoxies, isocyanates or polyester based adhesives. It is also possible to use chemical vapour deposition (CVD) methods to apply the primer such as parylene.

In a preferred embodiment, a primer is applied having a high modulus and/or low coefficient of expansion under high humidity conditions like 85% RH. Suitable primers are UV curable coatings based on acrylate functional oligomers like polyurethanes, moisture curable silica based coatings and the like. Preferably, the primer has—when cured—a Tg of 50° C. or higher.

The application of the primer can occur in-line (in the vacuum chamber) by first applying the primer, for example by vaporization, atomisation or CVD followed by deposition of the melam compound, or off-line, i.e applying the primer outside the vacuum chamber. The combination of in-line and off-line methods using different types of primers and adhesives is also possible. To achieve higher barrier properties, this process can be repeated many times to produce a composite structure consisting of the base substrate (for example PET), primer, melam layer, primer, melam layer, primer and so on. When the primer is applied on top of the melam layer, it may have as an additional function to protect the layer against action of humidity and mechanical wear. In the case of melam, it appeared that this triazine is unexpectedly good in withstanding water.

The substrate film may consist of a homogeneous material, or it may itself be non-homogeneous or a composite material. The substrate film may comprise various layers. Preferably, the film comprises a polymeric material. Examples of polymeric compounds are thermoplastic compounds and thermosetting compounds. Suitable examples of thermoplastic compounds include polyolefins, polyolefin-copolymers, polyvinylalcohol, polystyrenes, polyesters and polyamides. Suitable examples of such polymers include HD or LD polyethlylene (PE), LLD polyethylene, ethylene-propylene copolymers, ethylene-vinylacetate copolymer, polypropylene (PP), polyethylene terephtalate (PET) and high temperature stable polymers such polyethylene-2,6-naphthalate (PEN), liquid crystal polymer (LCP) and polyethersulfone (PES). These thermoplastic compounds are often used in the form of a film, either as such or oriented; such orientation may be biaxial, such as for example biaxially oriented polypropylene film (BOPP) and biaxially oriented polyethylene terephthalate (BOPET). The film may also comprise a layer of paper.

The plastic film may be coated with metal like Al, or metal oxides like AlOx, SiOx or mixtures thereof. The further layer of melam causes an increase in barrier properties, as well for oxygen transmission as for water vapour transmission. This may have been achieved by either protecting the (mechanically weak) metal (oxide) film, and/or by the intrinsic barrier properties of the melam coating. It was furthermore unexpected, that also this system was fully retortable. Layers of metal oxides have the advantage that these are transparent, and allow (also with melam as a further layer) to be micro-waveable.

The substrate with the crystalline melam layer can be printed with methods known in the art such as for example flexography, Gravure or letterpress printing. Suitable inks can be used, such as for example solvent or UV-curable inks. Printing can also be performed on the laminate.

The substrate with the crystalline melam layer will be further processed into a laminate. The further lamination step can be done by applying an adhesive, and further applying a film, or can be done by direct extrusion lamination.

As an adhesive, solvent based adhesives or solventless systems can be used. In a preferred embodiment of the invention, the adhesive has a good adhesion to the melam layer, and has a high strength, thereby aiding the coherency of the crystalline melam layer. Suitably, the adhesive has a low expansion, high Tg, high crosslink density and a high intrinsic water barrier. Examples of adhesives include various type of UV- or thermal curable resins based on acrylates, epoxies, isocyanates, polyester, and melamine formaldehyde resins.

In a further embodiment of the invention, the direct extrusion lamination is performed at its normal temperature of about 400° C. It is an advantage that the melam layer can withstand such high temperature, in contrast to melamine, which sublimes in such process.

In another embodiment of the invention, the direct extrusion lamination is performed at a relatively low temperature. A low temperature saves energy and may improve barrier characteristics. Generally, extrusion lamination is performed at about 400° C. to oxidise the extruded film in order to improve adhesion in other systems. It appeared that such high temperature is not necessary, so, preferably, the extrusion lamination is performed at a temperature of about 300° C. or lower.

The composite layer according the invention has favorable barrier properties, for example a low oxygen transmission rate (OTR) and a low water vapour transmission rate (WVTR), and is sufficient wear resistant. Therefore, the composite layer of the invention can be used as such in printing and laminating.

The OTR is generally measured in an atmosphere of 20- 30° C. and between 0% and 85% RH. The preferred values generally depend on the substrate. In case the substrate is biaxially oriented polypropylene (BOPP), the OTR generally will be about 400 cc/m²·24 h or less, preferably about 300 cc/m²·24 h or less and even more preferred about 200 cc/m²·24 h or less. Generally, in case of BOPP, the OTR will be about 5 cc/m²·24 h or higher, and for example may be about 50 cc/m²·24 h or higher. The OTR can be measured with suitable apparatus, such as for example with an OXTRAN 2/20 manufactured by Modern Control Co. In case the substrate is a PET film, the OTR generally will be about 50 cc/m²·24 h or less, preferably about 30 cc/m²·24 h or less and even more preferred about 10 cc/m²·24 h or less. Generally, in case of PET and OPA, the OTR will be about 0.3 cc/m²·24 h or higher, and for example may be about 0.5 or 1 cc/m²·24 h or higher

Water vapour permeability (WVTR) can measured with a PERMATRAN 3/31 manufactured by Modern Control Co, in an atmosphere of 25- 40° C. and between 50 and 90% RH. The preferred values will depend on the substrate. For example for BOPP the WVTR is generally about 3 g/m²·24 h or less, preferably about 2 g/m²·24 h or less, and more preferably about 1 g/m²·24 h or less. Generally, the vapour permeability will be about 0.1 g/m²·24 h or more, for example about 0.2 g/m²·24 h or more. For example for PET, the WVTR is generally about 10 g/m²·24 h or less, preferably 8 g/m²·24 h or less, preferably about 7 g/m²·24 h or less, and more preferably about 4 g/m²·24 h or less. Generally, the vapour permeability will be about 0.5 g/m²·24 h or more, for example about 2 g/m²·24 h or more.

Preferably, the laminate has an OTR and WVTR also for other substrates which conform to the values given in the former two paragraphs.

The composite layer, optionally further processed by for example printing and laminating, can be applied as or to all kind of packing materials, for example paper, sheet and films. The packing material protects very well its content from for example oxygen, in this way increasing shelf life of for example food products or personal care products or protecting electronic components from oxygen attack.

In one embodiment, the laminate comprises a PET or BOPP film as substrate, a crystalline melam layer as barrier layer, the laminate further comprising on the crystalline melam layer a pattern or figure and an adhesive and thereon a further film, which may be a polyolefin film, such as preferably a PE film. In another preferred embodiment, the polyolefin film has reverse printing instead of direct printing on the melam layer.

Vapour-depositing as such is a process known to the skilled person. A vapour-depositing step is often carried out at a reduced pressure, i.e. a pressure below atmospheric pressure. In the process according to the invention, the pressure preferably is below about 1000 Pa (10 mbar), preferably below about 100 Pa (1 mbar) even more preferably below about 10 Pa (0.1 mbar). In case the melam deposition takes place in a tool in which Al, or a metal-oxide is deposited, it is more preferable to have a pressure of below about 1×10⁻² mbar although it is equally possible to reduce the pressure at which the vapour-depositing step is carried out even further. The melam can be deposited in the same chamber as the metal(oxide); or in stead of the metal(oxide). In case both a metal(oxide) and melam is deposited, it is preferred to have separate chambers for the metal(oxide) deposition and the melam deposition. Generally, the vapour-depositing step is carried out at a pressure of about 10⁻⁴ mbar or higher, preferably about 10⁻³ mbar or higher.

The temperature at which melam is vaporized preferably is at about 300° C. or higher, preferably 330° C. or higher. At too high temperature, and/or long residence time, melam may degrade, so it is preferred, that the evaporation temperature is about 460° C. or lower, preferably 440° C. or lower. It appeared however, that such high temperatures can be allowed only very short time. In case melam is heated for only relatively short period like less than 20 min, preferably melam is coated at a temperature of 360° C. or higher, most preferably 370° C. or higher. The temperature preferably is about 390° C. or lower, most preferable 380° C. or lower

In a preferred embodiment, melam powder is evaporated in an evaporator placed in a vacuum chamber. The evaporator is a container which can be heated and has one or several slots where the melam vapour can leave the container. The vapour deposition process is controlled a.o. by the temperature profile of the powder, the vacuum outside the evaporator and the properties of the powder. The powder should be fine enough for a high evaporation rate. However, very fine powder is difficult to handle and may create (unwanted) dust during the coating process. The d50 of the powder is preferably less than 200 micron, more is preferably less than 100 micron, and most preferably between 60 and 10 micron (Sympatec laser diffraction technique applied on dry powder).

To obtain a high evaporation efficiency of the evaporator, the pressure outside the evaporator is preferably much lower than the equilibrium vapor pressure of the powder at the lowest temperature in the evaporator. The required vacuum will be deeper in the evaporators with a larger distance between the heating elements due to the lower temperatures at the same wall temperature. Preferably the pressure outside the evaporator should be less than 50% of the equilibrium vapour pressure of melam at the lowest temperature of the powder in the evaporator, more preferably less than 25% of the equilibrium vapour pressure of melam at the lowest temperature of the powder in the evaporator. The vapour pressure outside the evaporator is preferably less than 3*10⁻²mbar, more preferably less than 10⁻² mbar, and most preferably less than 3*10⁻³mbar. The equilibrium vapour pressure of melam varies between 3*10⁻³mbar and 10⁻¹ mbar in the practical range for powder vapor deposition.

Higher evaporation rates can be obtained at higher temperatures of the powder. However, melam decomposes at higher temperatures and an economic optimum between evaporation rate and melam decomposition should be found. The temperature of the melam powder is preferably between 390° C. and 290° C. For shorter residence times in the evaporator higher temperatures are allowed than for longer residence times. The required residence time is the time period wherein the evaporator should deliver the required performance. For required residence times in the evaporator longer than 2 hours, the temperature of the melam powder is preferably between 310° C. and 370° C., more preferably between 320° C. and 360° C. For required residence times in the evaporator longer than 5 hours, the temperature of the melam powder is preferably between 300° C. and 360° C., more preferably less than 350° C. A series of evaporators operated one after the other can be used for longer coating times. A series of evaporators can be operated simultaneously to obtain a thicker deposited layer. (Semi-) continuous supply of melam to the evaporator and removal of byproducts can also be applied. This method is especially suitable for higher melam temperatures (>360° C.).

In order to achieve optimal results, it is preferred to use fairly pure melam. Impure melam may cause even faster degradation of the melam and other components, yellowing or uneven deposition.

It is preferred to use melam with a purity grade of about 80% or higher, preferably 90% or higher. Impurities may be melamine or melem. It is in particular preferred, to have the amount of melamine during deposition at about 5% or lower. This can be initially achieved by preheating the melam at 200-250° C. at reduced pressure, to have the melamine evaporate before adding the melam to the roll-to-roll evaporator, or before starting the deposition. Further in the process—as of times over 15 or 20 min—it is necessary to carefully control the temperature and/or the time that the melam is subjected to the high temperature.

During the vapour-depositing step, the temperature of the substrate is about −60° C. or higher, preferably about −20° C. or higher, and most preferable about 0° C. or higher. The temperature of the substrate generally will be about +125° C. or lower, preferably about +80° C. or lower, and most preferably about 30° C. or lower.

Preferably, the substrate is kept at a temperature of about 5 ° C. or lower during vapour deposition.

The temperature of the substrate is defined herein as the temperature of the part of the substrate that is not being vapour-deposited. For example, if the vapour-depositing step is done on a film which is guided over a temperature-controlled coating drum, the temperature of the substrate is the temperature at which the coating drum is controlled, thus the temperature of the surface section of the film that is in immediate contact with the coating drum. In such a case, and in view of the fact that the to be deposited compounds often have a much higher temperature than 125° C., it will typically occur—as is known—that the temperature of the side of the substrate that is being deposited is higher than the temperature of the side that is not being deposited.

In one embodiment, the invention further relates to an apparatus for use in the process of the invention. The equipment for the application of melam, comprises a vacuum chamber, an evaporator with an oven comprising heating element and a shutter, over the length of the to be coated substrate, the heating element being able to heat the content of the oven up to 370-450° C.

In another embodiment, the invention further relates to an apparatus for use in a process of the invention in which measures are taken to preclude decomposition of melam. This equipment for the vapour deposition of melam, comprises a vacuum chamber, an evaporator with an oven comprising heating elements and a shutter, over the length of the to be coated substrate, the heating elements being able to heat the content of the oven up to 310-420° C., and in which the apparatus contains means to supply powder to the heating elements during the process under vacuum.

In another embodiment, which may be combined with the embodiments described above, the evaporator has heating elements which are positioned in such a way that the distance between the melam powder and the nearest heating element is less than 10 cm, preferably less than 8 cm, more preferably less than 6 cm and most preferably less than 4 cm. The evaporator is for example made from copper or stainless steel, with heating elements over the length over the oven. It is also possible, to have metal plates square in the oven, as to heat the melam also from the middle in compartments of e.g. 4×4 cm. In another embodiment, the oven is divided with one or more plates in the middle of the oven, which can be heated as to have the distance between the heated plates e.g. 2 cm. The oven also can have a spiral cord through the middle to heat the melam. The larger the distance between the powder and the heating element the larger the temperature difference of the powder will be with the temperature of the powder nearest to the heating element. The heating elements can have any shape e.g. flat, curved, cylindrical, spiral. The evaporator may contain one or more heating elements. The heating elements can be positioned in the container or at the sides of the container. The temperature profile depends on the powder properties: particle size, bulk density, thermal conductivity. In order to achieve a more homogeneous temperature, it is possible to continuously or intermittently mix the melam, e.g. with a screw mixer that slowly rotates back and forth.

For a high evaporation efficiency the slots in the evaporator for the efflux of the melam vapour should be large enough. The open area of the slots is preferably larger than 0.003 m² per kg of melam in the evaporator, more preferably larger than 0.006 m² per kg of melam in the evaporator. The distance of the melam powder to the nearest slot is preferably less than 0.3 m, more preferably less than 0.2 m, most preferably less than 0.15 m.

The distance between the vapour discharge slot and the film to be coated is usually between 0.01 and 0.15 m. Higher flow velocities of the vapour through the slot allow longer distances to the film. High flow velocities are reached if the pressure in the evaporator is at least twice as high as in the vacuum chamber.

The equipment preferably is installed in a web coater, where plastic substrates can be coated in a (semi)continuous process, also known as roll-to-roll. For example a webcoater, used for alumina deposition can be retrofitted with an oven suitable to heat and deposit melam.

The equipment can also be installed in coating apparatus for making solar panels or display panels. In such apparatus, generally rigid substrates are semi-continuously coated with leveling layers and barrier layers, such as in the present case one or more melam layers.

The invention will be further elucidated by the following non-limiting examples.

### Example 1 and Comparative Experiment A

In a boxcoater, coating experiments are performed. A 12 micron PET film is plasma treated and coated with melam at a vacuum of 10⁻⁴ mbar. The oven is heated for 10 min, and thereafter a shutter is put in the open position; the coating period is 1 minute. The temperature for evaporation of melam is 370° C. The films are laminated with a further plastic film (using a retortable adhesive, a OPA and CPP film) in order to measure the lamination strength while using a urethane adhesive, solvent based with ethyl-acetate as solvent.

The lamination strength was measured according to JIS Z0238 with a Tensilon instron tester, at a speed: of 30 mm/min, the angle between the two films was 90 degree.

The Oxygen transmission rate (OTR) was measured with OXTRAN 2/20 manufactured by Modem Control Cop., in an atmosphere of 23° C. and 0% RH.

Vapour permeability was measured with a PERMATRAN 3/31 manufactured by Modern Control Co, I an atmosphere of 40° C. and 90% RH. Results are given in table 1

TABLE 1

| | Example | |
|---|---|---|
| | 1 | A |
| In cc mm/m² day | Melam | Melamine |
| Oxygen transmission | 1 | 2 |
| 0% RH | | |
| Oxygen transmission | 1.5 | 100 |
| after 120° C. steam | | |
| Adhesion | 2.9 N/inch | 0 N/inch |

From these experiments it is clear that retort conditions do significantly decrease the barrier and adhesion properties of the melamine barrier layer, but have very little influence on the melam.

### Example 2

In an analogous way, a Polyetheleneterephthalate film of 12 micron (PET) is treated with melam (300 nm). Next, the melam layer is printed, causing no increase in transmission rates. The printed layer is further laminated with direct extrusion of PE at 400° C. The crystalline melam layer could withstand the heating by the films so made (15-35 micron) and showed good lamination strength. The OTR was 0.5, the WVTR 2.

### Example 3

In an analogous way, a PET film was provided with a crystalline melam layer. The initial OTR was 0.61 at 0% RH. After aging at 85% RH for 2 days, (where the OTR raised to 0.78), the OTR was only 0.51 when measured at 0% RH again.

### Example 4

A 12 μm PET film, coated with SiOx was further coated with melam in a roll-to-roll application. The coating speed was 20 m/min, and the temperature of the heating elements in the side walls of the melam evaporator was 350° C. The coating applied was—after a warm-up phase of about 20 min—continuously about 12 nm thick with a melam/melamine ratio (w/w) of 5.1 as measured with HPLC. The laminate was made with a lignin phenol formaldehyde (LPF) glue in ethylacetate, with OPA/CPP as top layers. The following properties were measured:

| Sample | OTR 0% RH | OTR 85% RH | WVTR |
|---|---|---|---|
| PET-Melam | 1.7 | 4.5 | 0.31 |
| Laminate | 1.3 | 1.0 | |
| Laminate after | 5.9 | 8.1 | 0.73 |
| retort | | | |
| Laminate after | 3.1 | | |
| Gelbo (80) | | | |

Retort was applied by heating a laminate for 30 min in a steam environment to 121° C.

Gelbo 80 means a Gelbo test with 80 cycles for condition D Full Flex

The above experiment shows that with PET, coated with SiOx and top coated with melam, high quality films are obtained, in which the SiOx is further protected with an active barrier layer.

### Example 5

BOPP was coated with 100 nm melam; the ratio (w/w) was 4.7 (melam:melamine). The OTR was about 20 in a laminate with CPP; and after retort 26 (at 0% RH).

### Example 6

PET was coated with Nanotool moisture curable silanolcoating.

Melam was deposited, and the water vapour transmission on the coated film was about 8.

1. Use of vapour deposited melam on a substrate, in applications requiring barrier properties resistant to high humidity.

2. Use according to claim 1 as barrier layer in retortable laminate.

3. Use according to claim 1 as undercoat and/or topcoat in metal coated paper.

4. Use according to claim 1 as barrier layer in solar or display applications.

5. Laminate comprising one or more of PP, PA or PET films, a melam barrier layer and an adhesive, able to withstand retort conditions (30 min steam environment at 121° C.).

6. Laminate according to claim 5, wherein the laminate comprises a metal oxide layer between the PP, PA or PET film and the melam layer

7. Laminate according to any one of claims 5-6, wherein the adhesion is at least 2.5 N/inch after retort.

8. Metal coated paper structure comprising calandered paper, clay, an undercoat, metal layer and a topcoat, wherein one or both of the coatings are melam.

9. Use or product according to any one of claims 1-8, wherein the layer contains melam and melamine in a ratio (w/w) melam/melamine of about 3 or higher, and of about 20 or lower.

10. Laminate comprising a plastic film as substrate and a crystalline triazine barrier layer, wherein the triazine layer contains melam and melamine in a ratio (w/w) melam/melamine of about 3 or higher, and of about 20 or lower.

11. Laminate according to claim 10, wherein the plastic film further comprises a metal or metal oxide layer.

12. Laminate according to claim 10, wherein the plastic film further comprises a coating layer with a high modulus or low expansion coefficient is subjected to 85% RH.

13. Use or product according to any one of claims 1-12, wherein the melam layer has a thickness of about 10 nm to 200 nm.

14. Equipment for the application of melam, comprising a vacuum chamber, an evaporator with an oven comprising heating element and a shutter over the length of the to be coated substrate, the heating element being able to heat the content of the oven up to 310-390° C. and comprising means to preclude decomposition of melam.

16. Process of making a melam coated film, wherein a roll of plastic is subjected to a roll-to-roll coating process in a vacuum chamber, such that a layer of melam is obtained on the film which has a ratio (w/w) of melam to melamine of higher than 3:1,

17. Process of making a melam coated substrates, wherein a substrate is subjected to a coating process in a vacuum chamber, such that a layer of melam is obtained on the substrate which has a ratio (w/w) of melam to melamine of higher than 3:1,

18. Process according to any one of claims 16-17, comprising means to preclude decomposition of the melam.

19. Process according to any one of claims 16-18, wherein the melam is heated to a temperature of about 310-390° C.

20. Process according to any one of claims 16-19, wherein the melam to melamine ratio (w/w) is about 50:1 or lower.
